(19) United States
(12) Patent Application Publication
(10) Pub. No.: US 2020/0168642 A1
(43) Pub. Date: May 28, 2020

(54) LASER IRRADIATION DEVICE, PROJECTION MASK, LASER IRRADIATION METHOD, AND PROGRAM

(71) Applicant: V Technology Co., Ltd., Yokohama (JP)

(72) Inventor: Michinobu Mizumura, Yokohama (JP)

(21) Appl. No.: 16/779,978

(22) Filed: Feb. 3, 2020

Related U.S. Application Data
(63) Continuation of application No. PCT/JP2018/027990, filed on Jul. 25, 2018.

(30) Foreign Application Priority Data
Aug. 10, 2017 (JP) 2017-155870

(51) Int. Cl. H01L 27/12; H01L 21/67; H01L 21/02; H01L 29/66; B23K 26/06; B23K 26/08; B23K 26/354

(52) U.S. Cl. CPC H01L 27/1285; H01L 21/67115; H01L 21/02592; H01L 21/02532; H01L 21/0262; G02F 1/1368; H01L 29/66765; B23K 26/0648; B23K 26/0876; B23K 26/354; H01L 21/02678

(57) ABSTRACT

A laser irradiation device is provided with a light source that generates laser light, and a projection lens for applying the laser light to predetermined regions of an amorphous silicon thin film deposited on a substrate. The laser irradiation device also arranged such that the projection lens includes a first projection lens for applying the laser light to first regions corresponding to a channel region of a thin film transistor, the first regions being a part of the predetermined regions, and a second projection lens for applying the laser light to second regions corresponding to predetermined elements included in a gate driver, the second regions being a part of the predetermined regions.

### TECHNICAL FIELD

This disclosure relates to formation of a thin film transistor, and particularly relates to a laser irradiation device, a projection mask, a laser irradiation method, and a program for irradiating an amorphous silicon thin film with laser light to form a polysilicon thin film.

### BACKGROUND

There is a technique in which, in an image display area of a TFT panel, a predetermined region of an amorphous silicon thin film is instantaneously heated by laser light to be polycrystallized, a polysilicon thin film having high electron mobility is formed, and the polysilicon thin film is used for a channel region of a thin film transistor.

For example, Japanese Unexamined Patent Application Publication No. 2016-100537 discloses that an amorphous silicon thin film is formed on a glass substrate and, thereafter, the amorphous silicon thin film is irradiated with laser light such as an excimer laser to be subject to a laser annealing so that the amorphous silicon thin film is crystallized as a polysilicon thin film by melting and solidifying in a short time. Japanese Unexamined Patent Application Publication No. 2016-100537 discloses that the processing makes it possible to form the channel region between a source and a drain of the thin film transistor as a polysilicon thin film having high electron mobility, and to improve a response time of the transistor.

In the TFT panel, a gate driver serves as a driving circuit that drives a thin film transistor of an image display area. In this regard, the TFT panel manufactured by using the technique disclosed in Japanese Unexamined Patent Application Publication No. 2016-100537 requires externally mounting the gate driver after creating the image display area, which is a factor in an increase in the manufacturing cost of the TFT panel.

It could therefore be helpful to provide a laser irradiation device, a projection mask, a laser irradiation method, and a program that can reduce the manufacturing cost of the TFT panel by eliminating the need of externally mounting of a gate driver in the TFT panel.

### SUMMARY

I thus provide:

A laser irradiation device may include: a light source that generates laser light; and a projection lens that irradiates a predetermined region of an amorphous silicon thin film deposited on a substrate with the laser light, in which the projection lens includes a first projection lens that irradiates first regions corresponding to a channel region of a thin film transistor with the laser light and being a part of the predetermined regions and a second projection lens that irradiates second regions corresponding to predetermined elements included in a gate driver with the laser light and being a part of the predetermined regions.

The second projection lens may be a microcylindrical lens that irradiates the second regions with the laser light.

The second projection lens may irradiate each of the second regions with the laser light two or more times using a plurality of cylindrical lenses included in the microcylindrical lens.

The laser irradiation device may further include a projection mask pattern arranged on the projection lens, and causes the laser light to transmit in a predetermined projection pattern, and in which the projection mask pattern includes first opening portions corresponding to the first regions and second opening portions corresponding to the second regions.

The first projection lens may be a microlens array that irradiates the first regions included in the substrate with the laser light, and an irradiation energy of the laser light with which the second projection lens irradiates the second region may be greater than an irradiation energy of the laser light with which the first projection lens irradiates the first regions.

The projection mask may be a projection mask arranged on a projection lens that radiates laser light generated from a light source, and includes: first opening portions that cause the laser light to transmit from a first projection lens included in the projection lens in first regions corresponding to a channel region of a thin film transistor and being a part of the amorphous silicon thin films that are deposited on the substrate, and second opening portions that cause the laser light to transmit from a second projection lens included in the projection lens in second regions corresponding to predetermined elements included in a gate driver and being a part of the amorphous silicon thin films.

In the projection mask, the second projection lens may be a microcylindrical lens capable of irradiating the second regions with the laser light, and the second opening portions cause the laser light from the microcylindrical lens to transmit in the second regions.

The laser irradiation method may include: generating step of generating laser light; and irradiating step of irradiating predetermined regions of an amorphous silicon thin film deposited on the substrate with the laser light; and in which in the irradiating step, first regions corresponding to a channel region of a thin film transistor and second regions corresponding to predetermined elements included in a gate driver are irradiated with the laser light, and the first regions and the second regions are parts of the predetermined regions.

In the laser irradiation method, in the irradiating step, each of the second regions may be irradiated with the laser light by using a microcylindrical lens.

The program stored in a computer readable non-transitory storage medium may cause a computer to execute: a generating function to generate laser light; and an irradiating function to irradiate predetermined regions of an amorphous silicon thin film deposited on a substrate with the laser light, in which, in the irradiating function, first regions corresponding to a channel region of a thin film transistor and second regions corresponding to predetermined elements included in a gate driver are irradiated with the laser light, and the first regions and the second regions are parts of the predetermined regions.

In the program, in the irradiating function, each of the second regions may be irradiated with the laser light by using a microcylindrical lens.

A gate driver may be formed on a substrate, and thus the need of externally mounting of a gate driver in a TFT panel is eliminated, thereby enabling provision of the laser irradiation device and others that can reduce a manufacturing cost of the TFT panel.

### BRIEF DESCRIPTION OF THE DRAWINGS

FIG. 1 is a drawing showing a configuration of a liquid crystal display system 1 in a first example.

FIG. 2 is a drawing showing a configuration of a laser irradiation device 10 in the first example.

FIG. 3 is a drawing showing a configuration of a projection lens 13 in the first example.

FIG. 4 is drawings showing configurations of a microcylindrical lens 17 in the first example.

FIG. 5 is a drawing for describing a condition that annealing treatment of the substrate is carried out using a microcylindrical lens in one example.

FIG. 6 is a configuration of an opening portion included in a projection mask pattern in one example.

FIGS. 7A and 7B are drawings showing configurations of the projection lens and the projection mask pattern in a modified form of the first example.

FIG. 8 is a drawing showing a configuration of a laser irradiation device in a second example.

### DESCRIPTION OF REFERENCE NUMBERS

10 Laser irradiation device
11 Laser light source
12 Coupling optical system
13 Projection lens
130 First projection lens
131 Second projection lens
14 Laser light
15 Projection mask pattern
151 and 152 Opening portion
16 Microlens array
160 Microlens
17 Microcylindrical lens
170 Cylindrical lens
18 Projection lens
20 Thin film transistor
21 Amorphous silicon thin film
22 Polysilicon thin film
23 Source
24 Drain
25 First region
26 Second region
30 Substrate
100 TFT panel
101 Liquid crystal display
102 Gate driver
103 Source driver
200 Controller
201 TCON
202 Voltage controller

### DETAILED DESCRIPTION

Hereinafter, examples will be specifically described with reference to the attached drawings.

### First Example

In a first example, in a laser irradiation device with which an annealing treatment is performed to a substrate, in addition to a microlens array, a microcylindrical lens is provided (included) in a projection lens that radiates laser light, whereby an annealing treatment to first regions corresponding to a gate driver and an annealing treatment to second regions corresponding to a channel region of a thin film transistor are simultaneously performed.

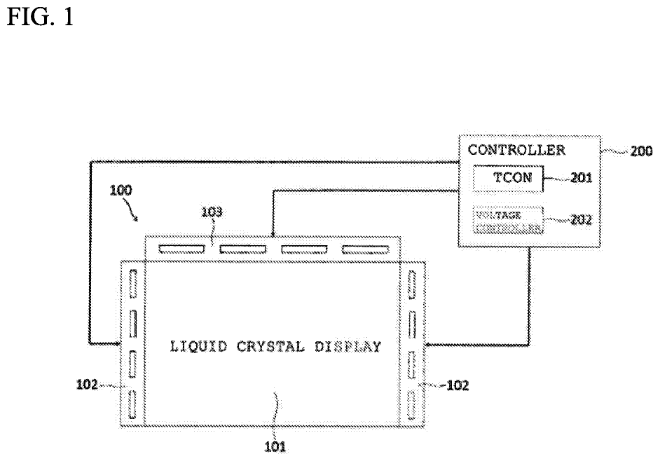

FIG. 1 is a drawing showing a configuration of a liquid crystal display system 1 in a first example. As illustrated in FIG. 1, in the first example, a liquid crystal display system 1 includes a TFT panel 100 and a controller 200. The TFT panel 100 includes a backlight (not shown).

The TFT panel 100 includes a thin film transistor for each pixel of a liquid crystal, and voltage of the TFT panel 100 is controlled for each pixel to change the amount of transmissions of light and a direction of the light that transmits in each pixel. As illustrated in FIG. 1, the TFT panel 100 includes a liquid crystal display 101 including a plurality of pixels, and a gate driver 102 and a source driver 103 that perform voltage control to each of the plurality of pixels.

The liquid crystal display 101 includes a plurality of pixels each having a thin film transistor 20. In addition, the gate driver 102 is a circuit that scans (drives) the plurality of pixels included in the liquid crystal display 101 per one row (one line). In addition, the source driver 103 is a circuit that gives image data (voltage according to information, including lightness and darkness, for example) to each pixel included in one row (one line) scanned by the gate driver 102. Thus, voltage of the thin film transistor 20 included in each of the plurality of pixels is controlled by the gate driver 102 and the source driver 103 to change the amount of transmission of each light of the pixel and the direction of light that transmits. Accordingly, the color of the TFT panel 100 can be changed for each pixel, and a predetermined image can be displayed on the entire TFT panel 100.

As illustrated in FIG. 1, the controller 200 includes a timing controller (TCON) 201 and a voltage controller 202, and controls each pixel included in the liquid crystal display 101. The TCON 201 is a logic circuit to adjust the timing so that one row (one line) scanned by the gate driver 102 matches one row (one line) in which a plurality of pixels which the source driver 103 gives image data are included, and supplies a pulse to the gate driver 102 and the source driver 103. The voltage controller 202 generates image data that the source driver 103 indicates to each pixel, and supplies the image data to the source driver 103.

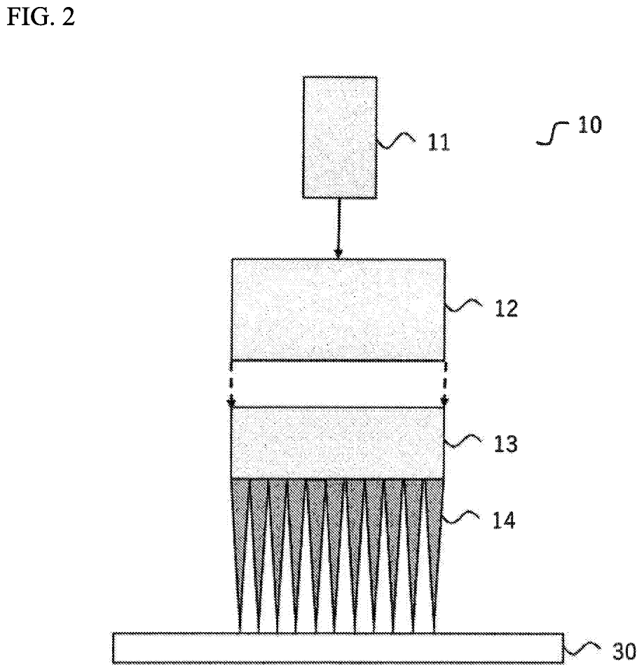

FIG. 2 is a drawing showing a configuration of a laser irradiation device 10 in a first example. As illustrated in FIG. 2, a laser irradiation device 10 is a device that, for example, irradiates predetermined regions of a substrate with laser light 14 to anneal, and polycrystallizing the predetermined regions in a manufacturing process of a semiconductor device such as the thin film transistor (TFT) 20.

The laser irradiation device 10 is used, for example, when forming the thin film transistor of pixels such as a peripheral circuit of a liquid crystal display. When forming such a thin film transistor, pattern formation of a gate electrode which includes of metal membranes such as aluminum, on a substrate 30 is first carried out by sputtering. Then, a gate dielectric film that includes a SiN film is formed on the entire surface of the substrate 30 by a low temperature plasma CVD method. Thereafter, an amorphous silicon thin film 21 is formed on the gate dielectric film with a plasma CVD method, for example That is, the amorphous silicon thin film 21 is formed (deposited) on the entire surface of the substrate 30 Finally, a silica dioxide (SiO₂) film is formed on the amorphous silicon thin film 21. Then, the laser irradiation device 10 illustrated in FIG. 1 irradiates the predetermined regions on the gate electrode of amorphous silicon thin film 21 with the laser light 14 to anneal, and the predetermined regions are polycrystallized to polysiliconize. The substrate 30 is a glass substrate, for example, but a material of the substrate does not necessarily need to be a glass material, and may be substrates made of any types of materials such as a resin substrate formed by materials such as resin.

As shown in FIG. 2, in the laser irradiation device 10, a beam system of the laser light 14 emitted from the laser light source 11 is expanded by a coupling optical system 12, and luminance distribution is uniformized. The laser light source 11 is, for example, an excimer laser that emits the laser light 14 having a wavelength such as 308 nm and 248 nm, in a predetermined repetition period.

Then, the laser light 14 transmits first opening portions 151 of a projection mask pattern 15 provided on a projection lens 13, is separated into a plurality of laser lights 14, and the predetermined regions of the amorphous silicon thin film 21 are irradiated with the plurality of laser lights 14. A projection mask pattern 15 is provided in the projection lens 13, and predetermined regions are irradiated with the laser lights 14 through the projection mask pattern 15. Then, the predetermined regions of the amorphous silicon thin film 21 are instantaneously heated and melted, and a part of the amorphous silicon thin film 21 becomes a polysilicon thin film 22.

Predetermined regions are first regions 25 corresponding to a channel region of the thin film transistor 20 and second regions 26 corresponding to predetermined elements included in the gate driver 102. That is, the laser irradiation device 10 irradiates the first regions 25 corresponding to the channel region of the thin film transistor 20 on the substrate 30, and the second regions 26 corresponding to the predetermined elements included in the gate driver 102 with the laser lights 14 emitted from the laser light source 11 through the projection lens 13. As a result, the first regions 25 corresponding to the channel region of the thin film transistor 20 on the substrate 30 and the second regions 26 corresponding to the predetermined elements included in the gate driver 102 becomes the polysilicon thin film 22.

The polysilicon thin film 22 has higher electron mobility than that of the amorphous silicon thin film 21, and can be used as the channel region of the thin film transistor 20 and predetermined elements (TFT elements) of the gate driver in the TFT panel.

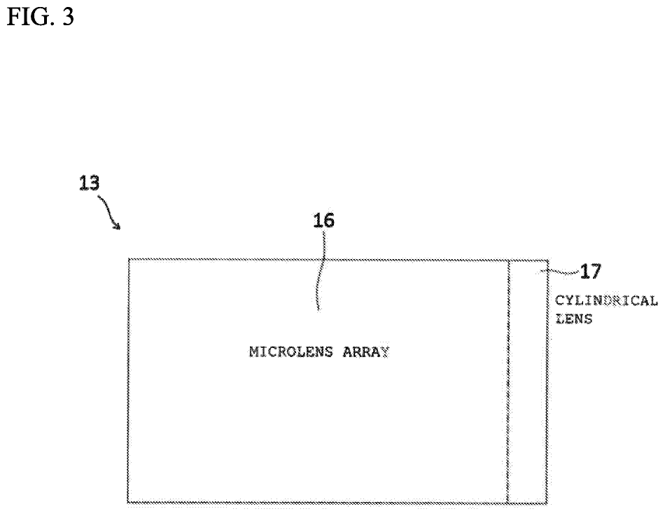

FIG. 3 is a drawing showing a configuration of the projection lens 13 in a first example. As illustrated in FIG. 3, the projection lens 13 includes a first projection lens 130 that irradiates the first regions 25 corresponding to the channel region of the thin film transistor 20 with the laser lights 14, and a second projection lens 131 that irradiates the second regions 26 corresponding to the predetermined elements included in the gate driver 102 with the laser lights 14.

The first projection lens 130 is a microlens array 16, for example. Using a plurality of microlenses 160 included in the microlens array 16 one by one, the laser irradiation device 10 irradiates the first regions 25 of the amorphous silicon thin film 21 with the laser lights 14 and the first regions 25 form the polysilicon thin film 22. The number of the microlenses 160 included in one line of the microlens array 16 is twenty. Therefore, the predetermined regions of the amorphous silicon thin film 21 formed (deposited) on the substrate 30 are irradiated with the laser lights 14 using twenty microlenses 160. The number of the microlenses 160 included in one row of the microlens array 16 is not limited to twenty, but may be any number. In addition, the number of the microlenses 160 included in one row (one line) of the microlens array 16 is eighty-three, for example, but it is not limited to this, but may be any number.

Annealing the predetermined regions by the first projection lens 130 forms the polysilicon thin film 22 and, thereafter, a source 23 and a drain 24 are formed at both ends of formed polysilicon thin film 22, whereby the thin film transistor 20 is created. The laser irradiation device 10 irradiates one thin film transistor 20 with the laser lights 14 using, for example, twenty microlenses 160 included in one column (or one row) of the microlens array 16. That is, the laser irradiation device 10 irradiates one thin film transistor 20 with twenty shots of the laser lights 14. As a result, in the thin film transistor 20, the predetermined regions of the amorphous silicon thin film 21 are instantaneously heated, melted and become a polysilicon thin film 22. In the laser irradiation device 10, the number of microlenses 160 included in one column (or one row) of the microlens array 16 is not limited to twenty, but may be any number as long as the number of microlenses 160 is plural.

The first projection lens 130 does not necessarily need to be a microlens array, and may radiate the laser lights 14 using one projection lens.

The second projection lens 131 is a microcylindrical lens 17, for example. A large amount of current is necessary for the predetermined elements (TFT element parts) of the gate driver 102 since the plurality of thin film transistors 20 included in one row (one line) of the liquid crystal display 101 are necessary to be scanned (driven). In addition, the current needs to be turned on and off at high speed to the predetermined elements (TFT elements) of the gate driver 102 since one column of the liquid crystal display 101 needs to be scanned for a short time. Therefore, the regions (the second regions 26) corresponding to the predetermined elements (TFT elements) of the gate driver 102 are greater than the channel region (the first regions 25) of the thin film transistor 20. Therefore, a problem arises that completion of the annealing treatment requires a long time if the annealing treatment of the second regions 26 is carried out with the microlens 160 included in the microlens array 16. Therefore, the annealing treatment cannot be carried out to the regions (the second regions 26) corresponding to the predetermined elements (TFT element parts) of the gate driver 102 simultaneously with the annealing treatment of the channel region of the thin film transistor 20, in the microlenses 160 included in the microlens array 16.

Accordingly, the annealing treatment of the second regions corresponding to the predetermined elements (TFT elements) of the gate driver 102 is carried out using a microcylindrical lens 17 including multiple cylindrical lenses 170 with a greater condensing degree of the laser lights 14 than that of the microlenses 160. Since the cylindrical lenses 170 are used, an irradiation energy of the laser lights 14 irradiated to the second regions corresponding to the predetermined elements (TFT elements) of the gate driver 102 is greater. Therefore, the time required for crystallization of the amorphous silicon thin film 21 in the second regions can be shortened and, thus, the annealing treatment can be carried out in a greater area, the annealing treatment can be carried out to the regions (the second regions) corresponding to the predetermined elements (TFT element parts) of the gate driver 102 simultaneously with the annealing treatment of the channel region of the thin film transistor 20.

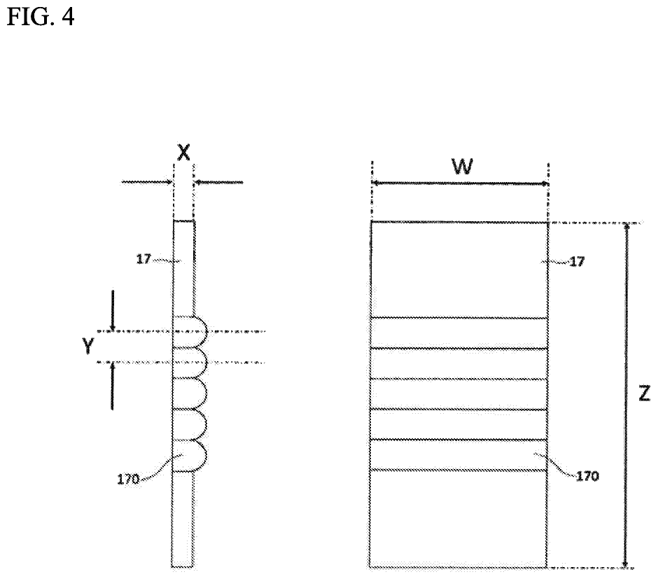

FIG. 4 is drawings showing configurations of the microcylindrical lens 17 in one example. As illustrated in FIG. 4, the microcylindrical lens 17 includes a plurality of cylindrical lenses 170. In the examples shown in FIG. 4, five cylindrical lenses 170 are included in the microcylindrical lens 17. The number of the cylindrical lenses 170 included in the microcylindrical lens 17 is not limited to five, but may be any number.

The left side of FIG. 4 is a side view of the microcylindrical lens 17. As illustrated at the left side of FIG. 4, a thickness X of the microcylindrical lens 17 is about 20.5 μm. In addition, a width Y of the cylindrical lens 170 included in the microcylindrical lens 17 is about 1.0395 μm. In addition, the right side of FIG. 4 is a front view of the microcylindrical lens 17. As illustrated at the right side of FIG. 4, a width W of the microcylindrical lens 17 is about 600 μm. In addition, a length Z of the microcylindrical lens 17 is about 1500 μm. These numeric values are mere examples, and numeric values of X, Y and Z are not limited to the above-mentioned numeric values.

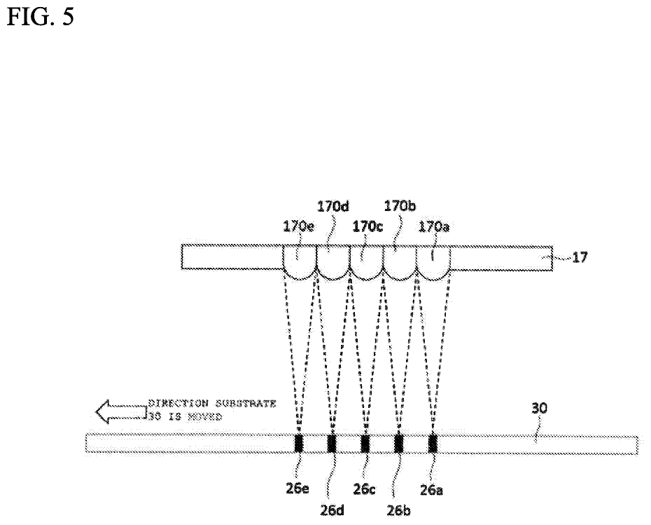

FIG. 5 is a drawing describing a condition that the annealing treatment is carried out for the substrate 30 on which the amorphous silicon thin film 21 is coated using the microcylindrical lens 17 which is the second projection lens 131 in one embodiment of the present invention. As illustrated in FIG. 5, the annealing treatment of the second regions 26 (regions corresponding to the predetermined elements (TFT elements) of the gate driver 102) of the substrate 30 is carried out using each of the cylindrical lenses 170 included in the microcylindrical lens 17 to form the polysilicon thin film 22.

As illustrated in FIG. 5, the second regions 26 are provided on the substrate 30, and each of the plurality of the second regions 26 is irradiated with the laser light 14 using the cylindrical lens 170. As illustrated in FIG. 5, a second region 26a is irradiated with a laser light 14 by a cylindrical lens 170a, and the second region 26a is subject to an annealing treatment. In addition, a second region 26b is irradiated with a laser light 14 by a cylindrical lens 170b, and the second region 26b is subject to an annealing treatment. In the same way, a second region 26c is irradiated with a laser light 14 by a cylindrical lens 170c and subject to an annealing treatment, a second region 26d is irradiated with a laser light 14 by a cylindrical lens 170d and subject to an annealing treatment, a second region 26e is irradiated with a laser light 14 by a cylindrical lens 170e, and subject to an annealing treatment.

Thereafter, the substrate 30 is moved by only a predetermined distance (interval of adjoining second regions 26). After movement of the substrate 30, the second region 26a is irradiated with the laser light 14 by the cylindrical lens 170b contiguous to the cylindrical lens 170a, and subject to an annealing treatment. In addition, in the same manner as the second region 26a, the second region 26b is irradiated with the laser light 14 by the cylindrical lens 170c contiguous to the cylindrical lens 170b, and subject to an annealing treatment. In the same manner as the second region 26a and the second region 26b, the second region 26c is irradiated with the laser light 14 by the cylindrical lens 170e and subject to an annealing treatment, and the second region 26d is irradiated with the laser light 14 by the cylindrical lens 170d. Thus, one second region 26 is irradiated with the laser light 14 by the number of the cylindrical lenses 170 included in the microcylindrical lens 17. As shown in FIG. 5, one second region 26 is irradiated with the laser light 14 by each of five cylindrical lenses 170 (namely, cylindrical lenses 170a to 170e), and subject to an annealing treatment.

After the substrate 30 is moved by a predetermined distance, the laser irradiation device 10 may irradiate the substrate 30 which stopped once with the laser lights 14, and may continue to irradiate the substrate 30 that continues to be moved with the laser lights 14.

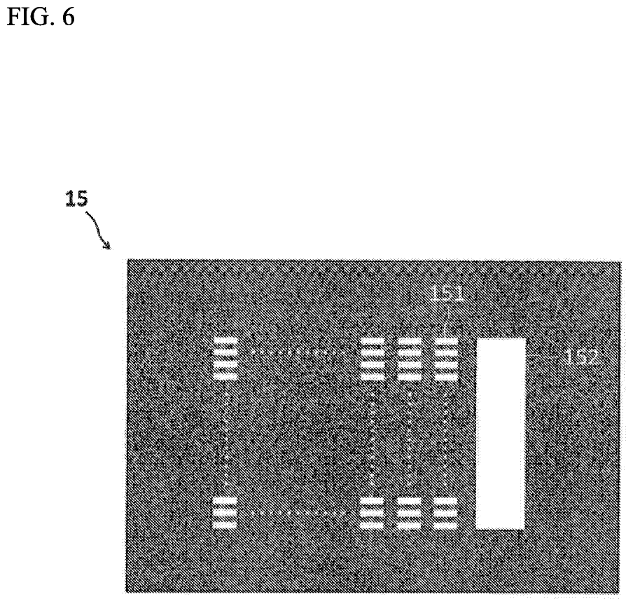

FIG. 6 shows a configuration of an opening portion 150 included in a projection mask pattern 15. The opening portion 150 includes first opening portions 151 provided corresponding to the microlens 160 included in the microlens array 16 which is the first projection lens 130, and second opening portions 152 provided corresponding to the microcylindrical lens 17 which is the second projection lens 131. The laser lights 14 transmit the first opening portions 151 of the projection mask pattern, and the regions (namely, the first regions 25 of the amorphous silicon thin film 21 formed (deposited) on the substrate 30) corresponding to the channel region of the thin film transistor 20 are irradiated with the laser lights 14. The width (the length of a shorter side) of the first opening portions 151 of the projection mask pattern 15 is about 50 μm. The length of the width is a mere example, and the length may be any length. The length of the longer side of the first opening portions 151 of the projection mask pattern 15 is about 100 μm, for example. The length of the longer side is a mere example, and may be any length.

The microlens array 16 radiates the laser lights 14 by contracting the projection mask pattern 15 to ⅕. As a result, the laser lights 14 that transmit the projection mask pattern 15 is contracted to a width of about 10 μm in the channel region. In addition, the laser lights 14 that transmit the projection mask pattern 15 are contracted to a length of about 20 μm in the channel region. The contraction percentage of the microlens array 16 may not be limited to ⅕, but may be any scale. In addition, the projection mask patterns 15, as illustrated in FIG. 5, are formed side by side at least by the number of microlenses 160.

On the other hand, the laser lights 14 transmit the second opening portions 152 of the projection mask pattern 15, and the second regions 26 that are regions corresponding to the predetermined elements (TFT elements) of the gate driver 102 are irradiated with the laser lights 14. The width (the length of a shorter side), and the length of the longer side of the second opening portions 152 of the projection mask pattern 15 are substantially same as the size of the microcylindrical lens 17. The size of the second opening portions 152 is a mere example, and may be any size.

Next, a method of producing a TFT panel 100 in the first example using the laser irradiation device 10 will be described.

First, the laser irradiation device 10 irradiates the first regions 25 (a portion to be the channel region, that are predetermined regions of the amorphous silicon thin film 21 formed (deposited) on the substrate 30) that are to be a channel region of the thin film transistor 20 and the second regions 26 that are regions corresponding to the predetermined elements (TFT elements) of the gate driver 102 by using the projection lens 13 illustrated in FIG. 3 with the laser lights 14. The first regions 25 are irradiated with the laser lights 14 using the microlens array 16 which is the first projection lens 130 included in the projection lens 13, and the second regions 26 are irradiated with the laser lights 14 using microcylindrical lens 17 which is the second projection lens 131 included in the projection lens 13. As a result, the amorphous silicon thin film 21 provided in the portion (portion to be a channel region) used as the channel region of the thin film transistor 20 is instantaneously heated, melted, and becomes a polysilicon thin film 22.

The substrate 30 is moved by a predetermined distance every time when the microlens array 16 and the microcylindrical lens 17 radiate the laser lights 14. The predetermined distance is a distance between a plurality of the thin film transistors 20 on the substrate 30. The laser irradiation device 10 stops irradiation of the laser lights 14 while moving the substrate 30 by the predetermined distance. The laser irradiation device 10 may stop irradiation of the laser lights 14, while moving the substrate 30.

After the substrate 30 is moved by a predetermined distance, the laser irradiation device 10 irradiates the first regions 25 irradiated with the laser lights 14 with one microlens 160 again using another microlens 160 included in the microlens array 16. In addition, the laser irradiation device 10 irradiates the second regions 26 irradiated with one cylindrical lens 170 again using another cylindrical lens 170 included in the microcylindrical lens 17. Since the microlens array 16 includes twenty rows of the microlenses 160, for example, the first regions 25 are irradiated with the laser lights 14 at least twenty times. In addition, the microcylindrical lens 17 includes five cylindrical lenses 170, for example, and thus the second regions 26 are irradiated with the laser lights 14 at least five times.

While repeating the above-mentioned process and irradiating the first regions 25 to be the channel regions of the thin film transistor 20 with twenty shots of the laser lights 14, using each of twenty microlenses 160 one by one, and the second regions 26 that are regions corresponding to the predetermined elements (TFT elements) of the gate driver 102 are irradiated using each of the five cylindrical lenses 170 one by one. As a result, while the polysilicon thin film 22 is formed in the first regions 25 on the substrate 30, the polysilicon thin film 22 is formed in the second regions 26 on the substrate 30.

Thereafter, in another process, a source 23 and a drain 24 are formed and, consequently, the thin film transistor 20 is formed.

As described above, in the first example to the projection lens 13, in addition to the microlens array 16 which is the first projection lens 130, the microcylindrical lens 17 which is the second projection lens 131 is provided and, thus, the first regions 25 corresponding to the channel region of thin film transistor 20 is subject to the annealing treatment, and simultaneously the second regions 26 corresponding to the gate driver 102 can be subject to the annealing treatment. Therefore, the gate driver 102 can be formed on the substrate and, thus, the need of externally mounting of the gate driver 102 in the TFT panel 100 is eliminated, and the laser irradiation device which can reduce the manufacturing cost of the TFT panel 100, for example, can be provided.

### Modified Example

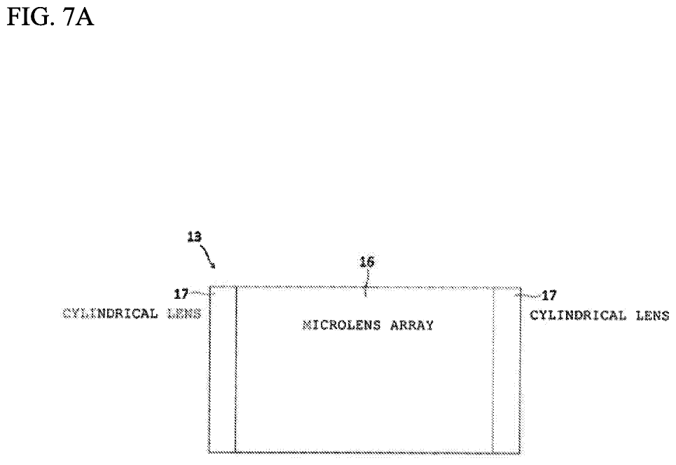

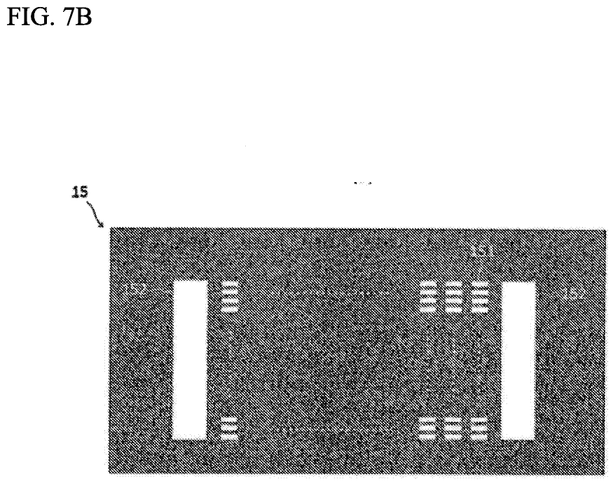

FIG. 7 shows configurations of the projection lens 13 and the projection mask pattern 15 in a modified example. As illustrated in FIG. 7A, a projection lens 13 in a modified example is different from the projection lens 13 illustrated in FIG. 3 in that the microcylindrical lens 17 which is the second projection lens 131 is provided at the right and left sides (regions that adjoin at the shorter sides of the microlens array 16) of the microlens array 16. That is, as illustrated in FIG. 7A, the projection lens 13 includes two microcylindrical lenses 17. The laser irradiation device 10 irradiates the second regions 26 that are regions corresponding to the predetermined elements (TFT elements) of the gate driver 102 with the laser lights 14 using one of the two microcylindrical lenses 17 included in the projection lens 13.

In addition, as illustrated in FIG. 7B, the second opening portions 152 are provided in the regions corresponding to two microcylindrical lenses 17 included in the projection lens 13 illustrated in FIG. 7A of the projection mask pattern 15 in the modified example. The projection mask pattern 15 illustrated in FIG. 7B is a mere example, and the second opening portions 152 may be provided only the regions corresponding to one microcylindrical lens 17 which the laser lights 14 transmit among two microcylindrical lenses 17 included in the projection lens 13.

As illustrated in FIG. 1, the gate driver 102 is formed at the right and left sides of the liquid crystal display 101 so that when using the projection lens 13 illustrated in FIG. 3 and the projection mask pattern 15 illustrated in FIG. 6, it is necessary to prepare the projection lens 13 and the projection mask pattern 15 to provide the gate driver 102 in the left side of the liquid crystal display 101, and the projection lens 13 and the projection mask pattern 15 to provide the gate driver 102 in the right side of the liquid crystal display 101. The projection mask pattern 15 illustrated in FIG. 3 and the projection lens 13 illustrated in FIG. 6 are examples of the projection lens 13 and the projection mask pattern 15 for providing the gate driver 102 at the right side of the liquid crystal display 101.

In contrast, use of the projection lens 13 and the projection mask pattern 15 as illustrated in FIG. 7 makes it possible to cause the laser lights 14 to transmit from the microcylindrical lens 17 at the left side of the projection lens 13 when providing the gate driver 102 at the left side of the liquid crystal display 101, and to cause the laser lights 14 to transmit from the microcylindrical lens 17 at the right side of the projection lens 13 when providing the gate driver 102 at the right side of the liquid crystal display 101. Thus, there is no need to prepare a separate projection lens 13 and projection mask pattern 15. Therefore, preparation of two or more types of projection lenses 13 and projection mask pattern 15 is unnecessary, which leads to save of cost, a storage place, and others.

### Second Example

A second example includes using one projection lens 18 instead of the microlens array 16 as the first projection lens 130 of the projection lens 13.

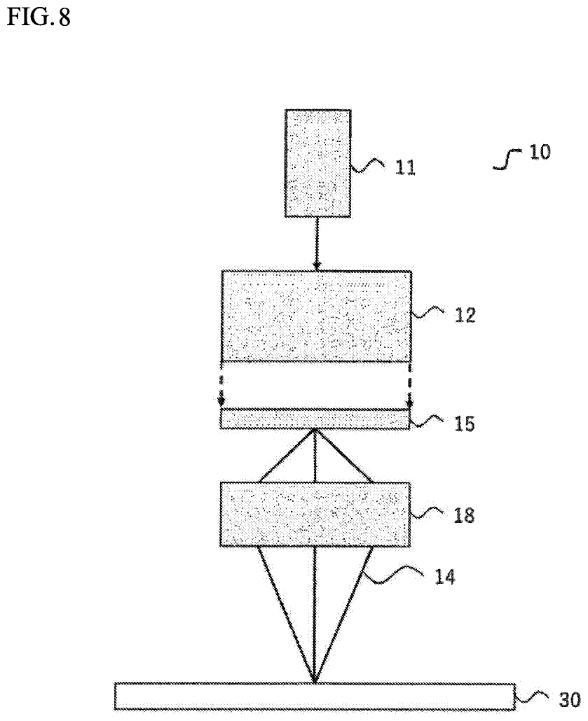

FIG. 8 is a drawing showing a configuration of a laser irradiation device 10 in the second example. As shown in FIG. 8, the laser irradiation device 10 in the second example includes a laser light source 11, a coupling optical system 12, a projection mask pattern 15, and a projection lens 13 including a projection lens 18. The laser light source 11 and the coupling optical system 12 have the same configuration as the laser light source 11 and the coupling optical system 12 in the first example as shown in FIG. 1, respectively, and thus detailed description will be omitted.

In the second example, when using the projection lens 18 instead of the microlens array 16 as the first projection lens 130, laser light 14 is converted by a magnification of the optical system of the projection lens 18. That is, the pattern of the projection mask pattern 15 is converted by the magnification of the optical system of the projection lens 18, and the first regions 25 of an amorphous silicon thin film 21 formed (deposited) on a substrate 30 are subject to an annealing treatment. The microcylindrical lens 17 irradiates the second regions 26 that are regions corresponding to the predetermined elements (TFT elements) of the gate driver 102 with the laser lights 14 in the same manner as the first example.

In the second example, the projection mask pattern 15 is a projection mask pattern 15 illustrated in FIG. 6 or 7B, for example. However, since the mask pattern of the projection mask pattern 15 is converted by the magnification of the optical system of the projection lens 18, the mask pattern of the projection mask pattern 15 may differ from the shape (area, size) of the projection mask pattern illustrated in FIG. 6 or 7B. Laser lights transmit the first opening portions 151 and the second opening portions 152 of the projection mask pattern 15, and the laser lights are radiated to the predetermined regions of the amorphous silicon thin film 21 by the projection lens 18. As a result, the predetermined regions of the amorphous silicon thin film 21 provided on the entire surface of the substrate 30 are instantaneously heated, melted, and the first regions 25 and the second regions 26 of the amorphous silicon thin film 21 become a polysilicon thin film 22.

The projection mask pattern 15 is converted by the magnification of the optical system of the projection lens 18, and the first regions 25 of the amorphous silicon thin film 21 formed (deposited) on the substrate 30 are subject to annealing treatment. For example, when the magnification of the optical system of the projection lens 18 is about twice, the mask pattern of projection mask pattern 15 is multiplied by ½ (0.5), and the predetermined regions of the substrate 30 are subject to an annealing treatment. The magnification of the optical system of the projection lens 18 is not limited to about twice, but may be any magnification. The projection mask pattern 15 is changed according to the magnification of the optical system of projection lens 18, and the predetermined regions on the substrate 30 are subject to an annealing treatment. For example, if the magnification of the optical system of the projection lens 18 is four, the mask pattern of projection mask pattern 15 is multiplied by about ¼ (0.25), and the first regions 25 of the amorphous silicon thin film 21 formed (deposited) on the substrate 30 are subject to an annealing treatment.

In addition, when the projection lens 18 forms an inverted image, the contracted image of the projection mask pattern 15 which the amorphous silicon thin film 21 formed (deposited) on the substrate 30 is irradiated forms a pattern obtained by rotation of 180 degrees along an optic axis of a lens of the projection lens 18. On the other hand, when the projection lens 18 forms an erection image, the contracted image of the projection mask pattern 15 in which the amorphous silicon thin film 21 formed (deposited) on the substrate 30 is irradiated remains the projection mask pattern 15 as it is.

Also in the second example, the laser irradiation device 10 radiates the laser lights 14 with a predetermined cycle, the substrate 30 is moved while the laser lights 14 are not radiated, and the first regions 25 and the second regions 26 of the amorphous silicon thin film 21 deposited on the substrate 30 are allowed to be irradiated with the laser lights 14.

As described above, in the second example, one projection lens 18 that serves as the first projection lens 130 of the projection lens 13 instead of microlens array 16 and the microcylindrical lens 17 that serves as the second projection lens 131 are included. Therefore, the first regions 25 corresponding to the channel region of the thin film transistor 20 are subject to the annealing treatment, and simultaneously the second region corresponding to the gate driver 102 can be subject to the annealing treatment. Therefore, since the gate driver 102 can be formed on the substrate, the need of externally mounting of the gate driver 102 in the TFT panel 100 is eliminated, and thus a laser irradiation device, for example, which can reduce manufacturing cost of the TFT panel 100 can be provided.

In the above description, when there is a description such as “vertical”, “parallel”, “planar”, “orthogonal”, or the like, the description do not indicate strict meaning of such terms. That is, the words “vertical”, “parallel”, “planar” and “orthogonal” allow tolerances and errors in design, manufacturing, or the like, and the words “vertical”, “parallel”, “plane” and “orthogonal” mean “substantially vertical”, “substantially parallel”, “substantially plane” and “substantially orthogonal”. The tolerance or error means a unit within a range which does not deviate from the configuration, operation and desired effect.

Further, in the above description, when there is a description such as “same”, “equal”, “different”, or the like in a dimension and a size of external shape, the descriptions do not indicate strict meaning of such terms. That is, the words “same”, “equal” and “different” allow tolerances and errors in design, manufacturing, or the like and may mean “substantially same”, “substantially equal” and “substantially different”. The tolerance or error means a unit within a range which does not deviate from the configuration, operation and desired effect.

Although my devices, masks, methods and programs have been described with reference to the drawings or examples, those skilled in the art can easily make various changes and corrections based on this disclosure. Therefore, the changes and corrections are included in the scope of the disclosure. For example, functions included in each means, each step, and the like can be rearranged not to be logically inconsistent, and a plurality of means, steps, and the like can be combined into one or divided. Further, the configurations described in the above-described examples may combined as appropriate.

What is claimed is:

1. A laser irradiation device comprising:
a light source that generates laser light; and
a projection lens that irradiates predetermined regions of an amorphous silicon thin film deposited on a substrate with the laser light,
wherein the projection lens includes:
a first projection lens that irradiates first regions corresponding to a channel region of a thin film transistor with the laser light, the first regions being a part of the predetermined regions; and
a second projection lens that irradiates second regions corresponding to predetermined elements included in a gate driver with the laser light, the second regions being a part of the predetermined regions.

2. The laser irradiation device according to claim 1, wherein the second projection lens is a microcylindrical lens that irradiates the second regions with the laser light.

3. The laser irradiation device according to claim 2, wherein the second projection lens irradiates each of the second regions with the laser light two or more times using a plurality of cylindrical lenses included in the microcylindrical lens.

4. The laser irradiation device according to claim 1, further comprising a projection mask pattern arranged on the projection lens, and causes the laser light to transmit in a predetermined projection pattern, wherein
the projection mask pattern includes first opening portions corresponding to the first regions and second opening portions corresponding to the second regions.

5. The laser irradiation device according to claim 2, further comprising a projection mask pattern arranged on the projection lens, and causes the laser light to transmit in a predetermined projection pattern, wherein
the projection mask pattern includes first opening portions corresponding to the first regions and second opening portions corresponding to the second regions.

6. The laser irradiation device according to claim 3, further comprising a projection mask pattern arranged on the projection lens, and causes the laser light to transmit in a predetermined projection pattern, wherein
the projection mask pattern includes first opening portions corresponding to the first regions and second opening portions corresponding to the second regions.

7. The laser irradiation device according to claim 1, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

8. The laser irradiation device according to claim 2, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

9. The laser irradiation device according to claim 3, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

10. The laser irradiation device according to claim 4, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

11. The laser irradiation device according to claim 5, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

12. The laser irradiation device according to claim 6, wherein
the first projection lens is a microlens array that irradiates the first regions included in the substrate with the laser light, and
an irradiation energy of the laser light with which the second projection lens irradiates the second regions is greater than an irradiation energy of the laser light with which the first projection lens irradiates the first regions.

13. A projection mask arranged on a projection lens, that radiates a laser light generated from a light source, the projection mask comprising:
first opening portions that cause the laser light to transmit from a first projection lens included in the projection lens in first regions corresponding to a channel region of a thin film transistor, the first regions being a part of amorphous silicon thin films which are deposited on a substrate; and
second opening portions that cause the laser light to transmit from a second projection lens included in the projection lens in second regions corresponding to predetermined elements included in a gate driver, the second regions being a part of the amorphous silicon thin films.

14. The projection mask according to claim 13, wherein
the second projection lens is a microcylindrical lens capable of irradiating the second regions with the laser light, and
the second opening portions cause the laser light from the microcylindrical lens to transmit in a plurality of the second regions.

15. A laser irradiation method comprising:
generating step of generating laser light; and
irradiating step of irradiating predetermined regions of an amorphous silicon thin film deposited on a substrate with the laser light, wherein
in the irradiating step, first regions corresponding to a channel region of a thin film transistor and second regions corresponding to predetermined elements included in a gate driver are irradiated with the laser light, the first regions and the second regions being parts of the predetermined regions.

16. The laser irradiation method according to claim 15, wherein, in the irradiating step, each of the second regions is irradiated with the laser light with a microcylindrical lens.

17. A computer readable non-transitory storage medium that stores a program, the program causes a computer to execute:
a generating function to generate laser light; and
an irradiating function to irradiate predetermined regions of an amorphous silicon thin film deposited on a substrate with the laser light,
wherein, in the irradiating function, first regions corresponding to a channel region of a thin film transistor and second regions corresponding to predetermined elements included in a gate driver are irradiated with the laser light, the first regions and the second regions being parts of the predetermined regions.

18. The storage medium according to claim 17, wherein, in the irradiating function, each of the second regions is irradiated with the laser light with a microcylindrical lens.
